(19) United States
(12) Patent Application Publication
(10) Pub. No.: US 2026/0173860 A1
(43) Pub. Date: Jun. 18, 2026

(54) DUAL SIDE METAL-INSULATOR-METAL (MIM) CAPACITOR FOR POWER INTEGRATION

(71) Applicant: International Business Machines Corporation, Armonk, NY (US)

(72) Inventors: Emmanuel Abreu, Sewaren, NJ (US); Tao Li, Slingerlands, NY (US); Qianwen Chen, Chappaqua, NY (US); Ruilong Xie, Niskayuna, NY (US); Joshua Mark Rubin, Albany, NY (US)

(21) Appl. No.: 18/981,351

(22) Filed: Dec. 13, 2024

(51) Int. Cl. H01L 23/522; H01L 23/528

(52) U.S. Cl. CPC H10W 20/496; H10W 20/427

(57) ABSTRACT

A semiconductor structure includes a multi-stack metal-insulator-metal (MIM) capacitor structure having a substrate and a frontside plate including fingers extending into the substrate. A first dielectric layer is located between the frontside plate and the substrate. The multi-stack MIM capacitor structure further has a backside plate and a second dielectric layer located between the backside plate and the substrate. The backside plate and the second dielectric layer conform to a topography of the fingers of the frontside plate and the first dielectric layer.

### BACKGROUND

The present disclosure generally relates to the electrical, electronic, and computer arts and, more particularly, to integrated circuits (ICs), semiconductor devices, and the like.

The capacitance value of classical two-dimensional capacitors (“caps”) depends on the electrode surface area (for a parallel plate capacitor, the capacitance is the area of the plates times the permittivity of the material separating the plates divided by the distance between them). Three-dimensional structures enable higher density capacitors and can employ pillars or trenches. The vertical structure will, however, typically limit thickness scaling.

A Metal-Insulator-Metal (MIM) capacitor includes parallel plates and can be formed by two metal planes separated by a thin dielectric; such capacitors are typically used in radio frequency (RF) circuits for oscillators, phase-shift networks, coupling, bypass capacitance, and the like. MIM capacitors are also useful for analog applications, because they are highly linear in nature and have a good dynamic range.

Current MIM capacitors include vias landing on MIM capacitor plates or vias penetrating MIM capacitor plates with sidewall contact. In some cases, such vias can be back-end-of-line (BEOL) vias, connecting the MIM capacitor to a BEOL wiring layer and/or vias connecting the MIM capacitor to a backside power distribution network (BSPDN). With advancements in technology there is a constant demand for reductions in footprint of such circuitry and increased capacitance capability of the MIM capacitor, and thus improved functionality of integrated circuits, semiconductor devices, and the like.

### BRIEF SUMMARY

Principles of the invention provide techniques for a dual side MIM capacitor for power integration. In one aspect, an exemplary semiconductor structure includes a multi-stack metal-insulator-metal (MIM) capacitor structure having a substrate, a frontside plate including fingers extending into the substrate, a first dielectric layer located between the frontside plate and the substrate, a backside plate, and a second dielectric layer located between the backside plate and the substrate. The backside plate and the second dielectric layer conform to a topography of the fingers of the frontside plate and the first dielectric layer.

An aspect of an exemplary method of forming a semiconductor structure includes forming a first side of a dual side multi-stack metal-insulator-metal (MIM) capacitor, the first side having a frontside plate and a first dielectric layer located between the frontside plate and a substrate of the dual side MIM capacitor, in which the frontside plate includes fingers extending into the substrate; forming connections to a back-end-of-line (BEOL) wiring layer; bonding the first side of the dual side multi-stack MIM capacitor and the BEOL wiring layer to a carrier wafer; flipping the semiconductor structure to face the substrate upward; removing a portion of the substrate, and recessing a remaining substrate to a level where the first dielectric layer is exposed, the recession forming a trench; forming, by following a topography of the fingers of the frontside plate, the first dielectric layer, and the trench, a second side of the dual side multi-stack MIM capacitor, the second side having a backside plate and a second dielectric layer between the substrate and the backside plate; filling, at a back side of the substrate, with an interlayer dielectric (ILD); and forming a backside power distribution network (BSPDN).

In another aspect, a hardware description language (HDL) design structure is encoded on a machine-readable data storage medium. The HDL design structure includes elements that when processed in a computer-aided design system generate a machine-executable representation of a semiconductor structure, as described.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action other than by performing the action, the action is nevertheless performed by some entity or combination of entities.

Techniques, as disclosed herein, can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 illustrates an exemplary multi-stack metal-insulator-metal (MIM) capacitor for

power integration according to aspects of the invention;

FIGS. 2-6 illustrate a method of making a multi-stack metal-insulator-metal (MIM) capacitor for power integration according to aspects of the invention;

FIG. 7 illustrates a transistor structure for cointegration with a multi-stack metal-insulator-metal (MIM) capacitor for power integration according to aspects of the invention;

FIG. 8 is a flow diagram that illustrates a method of making a multi-stack metal-insulator-metal (MIM) capacitor for power integration according to aspects of the invention;

FIG. 9 illustrates a computing environment according to an embodiment of the present invention (e.g., for implementing a design process such as that of FIG. 10); and

FIG. 10 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary semiconductor structure 1000 includes a multi-stack metal-insulator-metal (MIM) capacitor structure 1001 having a substrate 1003, a frontside plate 1005 including fingers 1007 extending into the substrate 1003, a first dielectric layer 1011 located between the frontside plate 1005 and the substrate 1003, a backside plate 1015, and a second dielectric layer 1013 located between the backside plate 1015 and the substrate 1003. The backside plate 1015 and the second dielectric layer 1013 conform to a topography of the fingers 1007 of the frontside plate 1005 and the first dielectric layer 1011. Technical benefits of a backside plate 1015 and a second dielectric layer 1013 conforming to a topography (i.e., following the topography) of fingers 1007 of a frontside plate 1005 and a first dielectric layer 1011 include the backside plate 1015 and the second dielectric layer 1013 leveraging the same real estate of the fingers 1007 of the frontside plate 1005 and the first dielectric layer 1011, reducing the overall footprint of the multi-stack MIM capacitor 1001. Further, technical benefits of this leveraging of the same real estate include an increase in capacitance of the multi-stack MIM capacitor 1001 due to a reduction in the distance between plates and dielectric layers (as the capacitance is the area of the plates times the permittivity of the material separating the plates divided by the distance between them), as opposed to previous approaches.

In a further option, the substrate 1003 can be between 50 nm and 1 μm thick. For example, in some embodiments, the substrate 1003 can be approximately 150 nm thick. Technical benefits of the thickness of the substrate 1003 being between 50 nm and 1 μm thick (e.g., approximately 150 nm in some embodiments) include that it can provide for compatibility with a backside power distribution network and an optional buried power rail (BSPDN BPR) scheme for power integration.

Continuing with options, the substrate 1003 can include a front side 1019 and the frontside plate 1005 and the first dielectric layer 1011 can be located at the front side 1019 of the substrate 1003. Further, optionally, the semiconductor structure 1000 can include a back-end-of-line (BEOL) wiring layer 1023 in which the multi-stack MIM capacitor structure 1001 can be connected to the BEOL wiring layer 1023 of the semiconductor structure 1000. For example, the BEOL wiring layer 1023 can be connected to the multi-stack MIM capacitor structure 1001 at the front side 1019 of the substrate 1003. Further, optionally, the semiconductor structure 1000 can include a transistor structure, in which the MIM capacitor structure 1001 can be co-integrated with the transistor structure.

In yet another option, the substrate 1003 can further include a back side 1021 and the second dielectric layer 1013 and the backside plate 1015 can be located at the back side 1021 of the substrate 1003. Further, in optional further aspects, the fingers 1007 of the frontside plate 1005 and the first dielectric layer 1011 can extend through the substrate 1003 from the front side 1019 of the substrate 1003 through the back side 1021 of the substrate 1003.

In optional further aspects, the semiconductor structure 1000 can further include a backside power distribution network (BSPDN) 1025. The BSPDN 1025 can be connected to the multi-stack MIM capacitor structure 1001. In some examples, the BSPDN 1025 can be connected to the multi-stack MIM capacitor structure 1001 at the back side 1021 of the substrate 1003.

Optionally, the frontside plate 1005 can be of a first material and the backside plate 1015 can be of a second material, different than the first material. Further, optionally, the frontside plate 1005 can be of a first thickness and the backside plate 1015 can be of a second thickness, different than the first thickness.

In some options, the first dielectric layer 1011 can be of a first dielectric material and the second dielectric layer 1013 can be of a second dielectric material, different than the first dielectric material. Further, optionally, the first dielectric layer 1011 can be of a first dielectric thickness and the second dielectric layer 1013 can be of a second dielectric thickness, different than the first dielectric thickness.

Optionally, in further aspects, the semiconductor structure 1000 can further include a shared plate 1009, located at the front side 1019 of the substrate 1003 between the first dielectric layer 1011 and the substrate 1003, and a third dielectric layer 1017 located between the shared plate 1009 and the substrate 1003. The shared plate 1009 and the third dielectric layer 1017 can extend through the substrate 1003 from the front side 1019 of the substrate 1003 through the back side 1021 of the substrate 1003.

In further options, the frontside plate 1005 can be of a first material, the backside plate 1015 can be of a second material, and the shared plate 1009 can be of a third material, different than the first material and the second material. Further, the frontside plate 1005 can be of a first thickness, the backside plate 1015 can be of a second thickness, and the shared plate 1009 can be of a third thickness, different than the first thickness and the second thickness.

In still further options, the first dielectric layer 1011 can be of a first dielectric material, the second dielectric layer 1013 can be of a second dielectric material, and the third dielectric layer 1017 can be of a third dielectric material, different than the first dielectric material and the second dielectric material. Further, the first dielectric layer 1011 can be of a first dielectric thickness, the second dielectric layer 1013 can be of a second dielectric thickness, and the third dielectric layer 1017 can be of a third dielectric thickness, different than the first dielectric thickness and the second dielectric thickness.

An aspect of an exemplary method of forming a semiconductor structure 1000 includes forming a first side of a dual side multi-stack metal-insulator-metal (MIM) capacitor 1001, the first side including a frontside plate 1005 and a first dielectric layer 1011 located between the frontside plate 1005 and a front side of a substrate 1003 of the dual side multi-stack MIM capacitor 1001, in which the frontside plate 1005 includes fingers 1007 extending into the substrate 1003; forming connections to a back-end-of-line (BEOL) wiring layer 1023; bonding the first side of the dual side multi-stack MIM capacitor 1001 and the BEOL wiring layer 1023 to a carrier wafer 1029; flipping the semiconductor structure 1000 to face a back side of the substrate 1003 upward, removing a portion of the substrate 1003, and recessing a remaining substrate 1003 to a level where the first dielectric layer 1011 is exposed, the recession forming a trench 1031; forming, by following a topography of the fingers 1007 of the frontside plate 1005, the first dielectric layer 1011, and the trench 1031, a second side of the dual side multi-stack MIM capacitor 1001, the second side including a backside plate 1015 and a second dielectric layer 1013 between the back side of the substrate 1003 and the backside plate 1015; filling, at the back side 1021 of the substrate 1003, with an interlayer dielectric (ILD) 1035; and forming a backside power distribution network (BSPDN) 1025. Technical benefits include a method of making a dual side multi-stack MIM capacitor 1001 that includes a minimal distance between the first side of the dual side multi-stack MIM capacitor 1001 and the second side of the dual side multi-stack MIM capacitor 1001 improving capacitance and reducing the overall footprint of the multi-stack MIM capacitor 1001.

Optionally, the frontside plate 1005 can be formed on a front side 1019 of the substrate 1003 and the backside plate 1015 can be formed on the back side 1021 of the substrate 1003.

Optionally, the backside plate 1015 and the second dielectric layer 1013 can be formed after at least partially recessing the remaining substrate 1003 from the back side 1021 of the substrate 1003. In another option, the backside plate 1015 and the second dielectric layer 1013 can be formed after fully recessing the remaining substrate 1003 from the back side 1021 of the substrate 1003. Further, optionally, removing of the portion of the substrate 1003 can include reducing a thickness of the substrate 1003 down to an etch stop layer 1037 and recessing the remaining substrate 1003 to the level where the first dielectric layer 1011 is exposed can include removal of the etch stop layer 1037. In a further option, the substrate 1003 can be recessed to a thickness between 50 nm and 1 μm. For example, the substrate 1003 can be approximately 150 nm thick. One technical benefit of the thickness of the substrate 1003 being between 50 nm and 1 μm thick is to provide for compatibility with a backside power distribution network buried power rail (BSPDN BPR) scheme for power integration, though examples are not so limited.

In yet another option, the BEOL wiring layer 1023 can be connected to the first side of the dual side multi-stack MIM capacitor 1001 and the BSPND 1025 can be connected to the second side of the dual side multi-stack MIM capacitor 1001.

Further, in yet another option, the first dielectric layer 1011 can include a plurality of side walls 1032, the substrate 1003 can be at least partially or fully recessed from the back side 1021 of the substrate 1003 forming the trench 1031 between a first side wall 1032a and a second side wall 1032b of the plurality of side walls 1032, and forming the second dielectric layer 1013 and the backside plate 1015 to follow the topography of the fingers 1007 of the frontside plate 1005, the first dielectric layer 1011, and the trench 1031 can include forming the second dielectric layer 1013 and the backside plate 1015 between the first side wall 1032a and the second side wall 1032b of the plurality of side walls 1032. A technical benefit is the creating of the backside plate 1015 and the second dielectric layer 1013 on the surface of the first dielectric layer 1011 and the substrate 1003, reducing overall size (i.e., footprint) of the circuitry and providing for an increase in capacitance due to a reduction in distance between the first side and the second side of the dual side multi-stack MIM capacitor 1001. Further, a technical benefit includes the need to have only a single trench patterning performed (located on the back side 1021 of the substrate 1003). Additionally, technical benefits for recessing the substrate 1003 from the back side 1021 of the substrate 1003 include allowing for the substrate 1003 to be recessed without including a process to flip the semiconductor structure 1000 back over to form the backside plate 1015 and second dielectric layer 1013 of the dual side multi-stack MIM capacitor 1001 after the bonding process to the carrier wafer 1029.

Optionally, in further aspects, the method of forming the semiconductor structure 1000 can include forming a first shared plate 1009 and a third dielectric layer 1017 on the first side of the dual side multi-stack MIM capacitor 1001, in which the first dielectric layer 1011 can be located between the frontside plate 1005 and the first shared plate 1009 and the third dielectric layer 1017 can be located between the first shared plate 1009 and the substrate 1003 of the dual side multi-stack MIM capacitor 1001. As such, forming the second dielectric layer 1013 and the backside plate 1015 can include further following a topography of the first shared plate 1009 and the third dielectric layer 1017 and can include forming the second dielectric layer 1013 and the backside plate 1015, at least in part, between a first side wall 1033a and a second side wall 1033b of a plurality of side walls 1033 of the third dielectric layer 1017.

Further, optionally, the method of forming the semiconductor structure 1000 can include forming a second shared plate and a fourth dielectric layer on the first side of the dual side multi-stack MIM capacitor 1001, in which the first dielectric layer 1011 can be located between the frontside plate 1005 and the first shared plate 1009, the third dielectric layer 1017 can be located between the first shared plate 1009 and the second shared plate, and the fourth dielectric layer can be located between the second shared plate and the substrate 1003 of the dual side multi-stack MIM capacitor 1001. As such, forming the second dielectric layer 1013 and the backside plate 1015 can include further following a topography of the second shared plate and the fourth dielectric layer and can include forming the second dielectric layer 1013 and the backside plate 1015, at least in part, between a first side wall and a second side wall of a plurality of side walls of the fourth dielectric layer. Technical benefits of having multiple plates and dielectric layers include an increase in capacitance capabilities of the multi-stack MIM capacitor 1001, due to the minimal spacing between the multiple plates and dielectric layers of the multi-stack MIM capacitor 1001, while utilizing minimal real estate.

In another aspect, a hardware description language (HDL) design structure is encoded on a machine-readable data storage medium. The HDL design structure includes elements that when processed in a computer-aided design system generate a machine-executable representation of a semiconductor structure, as described.

Techniques as disclosed herein can provide substantial beneficial technical effects. Some embodiments may not have these potential advantages and these potential advantages are not necessarily required of all embodiments. By way of example only and without limitation, one or more embodiments can provide one or more of:

Allow for a reduced footprint, increased capacitance, and increased manufacturing
efficiency for semiconductor structure using multi-stack MIM capacitors:
by recessing a substrate from the back side of the substrate.
by reducing the distance between the first side and the second side of multi-stack MIM capacitor.
by forming a first dielectric layer on the surface of a substrate and a second dielectric layer and a backside plate on the surface of the first dielectric layer.
by leveraging the same real estate to form the second side of the multi-stack MIM capacitor as the first side of the multi-stack MIM capacitor.
by forming a multi-stack MIM capacitor using a single trench patterning process.

One or more embodiments advantageously provide multi-stack MIM capacitors that can provide an increase in capacitance in a smaller footprint and, thus, a smaller device, with an improved efficiency during manufacturing. Aspects of the invention provide techniques for providing a multi-stack MIM capacitor with a substrate recessed from the back side of the semiconductor structure when back side processing is performed. Aspects of the invention further provide a second dielectric layer and backside plate located on a back side of the substrate of the semiconductor structure which can leverage the same real estate as a first dielectric layer and a frontside plate located on the front side of the substrate.

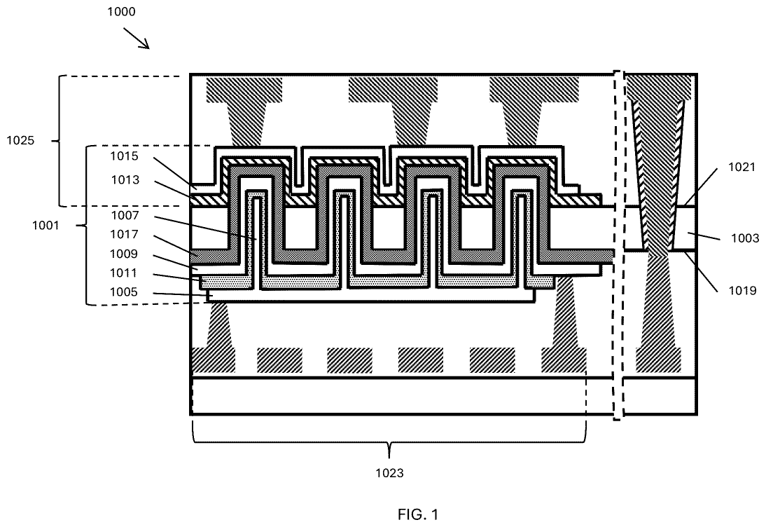

Referring to FIG. 1, an exemplary multi-stack metal-insulator-metal (MIM) capacitor structure 1001 for power integration is illustrated. Here, a semiconductor structure 1000 including the multi-stack MIM capacitor structure 1001 is shown. In some embodiments, the semiconductor structure 1000 can be a chip, part of an assembly of chips, or chiplets in 3D or 2.5D. The multi-stack MIM capacitor structure 1001 can be formed on a substrate 1003 during manufacturing of the semiconductor structure 1000. For example, the multi-stack MIM capacitor structure 1001 can include the substrate 1003. The substrate 1003 can include silicon, glass, or any other material (e.g., organic substrates) suitable for HI and/or BSPDN applications.

The substrate 1003 includes a front side 1019 of the substrate 1003 and a back side 1021 of the substrate 1003. A frontside plate 1005 and a first dielectric layer 1011 are located on the front side 1019 of the substrate 1003. The first dielectric layer 1011 is located between the frontside plate 1005 and the substrate 1003. The frontside plate 1005 includes fingers 1007 that extend upward from the front side 1019 of the substrate 1003 through the back side 1021 of the substrate 1003. Accordingly, the first dielectric layer 1011 follows a topography of the fingers 1007 of the frontside plate 1005 and extends from the front side 1019 of the substrate 1003 upwards through the back side 1021 of the substrate 1003.

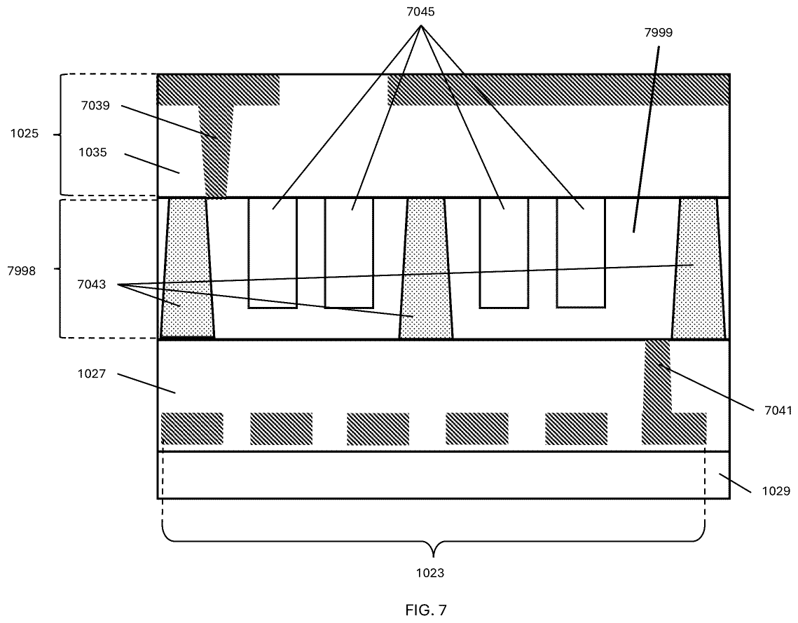

Further, a backside plate 1015 and a second dielectric layer 1013 are located on the back side 2021 of the substrate 1003. As such, the substrate 1003 can, at least partially, separate the frontside plate 1005 and the first dielectric layer 1011 from the backside plate 1015 and the second dielectric layer 1013. The backside plate 1015 and the second dielectric layer 1013 follow the topography of the fingers 1007 of the frontside plate 1005 and the first dielectric layer 1011. Connected at the front side 1019 of the substrate 1003 is a back-end-of-line (BEOL) wiring layer 1023. Connected at the back side 1021 of the substrate 1003 is a backside power distribution network (BSPDN) 1025. While not shown in FIG. 1 for simplicity, one skilled in the art will realize an additional transistors area (e.g., example transistor structure/transistor area as illustrated in FIG. 7) compatible with a BSPDN buried power rail (BPR) scheme.

Optionally, the multi-stack MIM capacitor structure 1001 can include additional plates and dielectric layers. For example, as illustrated in FIG. 1, the multi-stack MIM capacitor structure 1001 can include a shared plate 1009 and a third dielectric layer 1017. In some embodiments, the shared plate 1009 and the third dielectric layer 1017 can be located on the front side 1019 of the substrate 1003. That is, the shared plate 1009 can be located on the front side 1019 of the substrate 1003 between the first dielectric layer 1011 and the third dielectric layer 1017 and the third dielectric layer 1017 can be located between the shared plate 1009 and the substrate 1003. In still further embodiments, a second shared plate (not shown) and a fourth dielectric layer (not shown) can be located on the front side 1019 of the substrate 1003. That is, the second shared plate can be located between the third dielectric layer 1017 and the fourth dielectric layer and the fourth dielectric layer can be located between the second shared plate and the substrate 1003.

In some embodiments, it can be contemplated that further shared plates and dielectric layers (i.e., multiple shared plates and dielectric layers) can be located on the front side 1019 of the substrate 1003 in an alternating pattern similar to the frontside plate 1005, first dielectric layer 1011, shared plate 1009, and third dielectric layer 1017 shown in FIG. 1. Though the shared plate 1009 and the third dielectric layer 1017 are shown on the front side 1019 of the substrate 1003, examples are not so limited and it can be contemplated that the shared plate 1009 and the third dielectric layer 1017 can be located on the back side 1021 of the substrate 1003. That is, the shared plate 1009 can be located between the second dielectric layer 1013 and the third dielectric layer 1017 and the third dielectric layer 1017 can be located between the shared plate 1009 and the substrate 1003 (not shown). Further, multiple shared plates and dielectric layers can be located on the back side 1021 of the substrate 1003 and/or can be located on a combination of the front side 1019 and the back side 1021 of the substrate 1003. In each scenario, the dielectric layers, the shared plates, and the backside plate 1015 can follow the topography of the fingers 1007 of the frontside plate 1005.

In some embodiments, the frontside plate 1005, backside plate 1015, shared plate 1009, and any additional optional plates (e.g., additional shared plates) can include Titanium (Ti), Titanium-Nitride (TiN), Tantalum (Ta), Tantalum-Nitride (TaN), Cobalt (Co), or any combination thereof. Each plate can include the same material, though examples are not so limited and one or more plates can include different materials and/or combinations of materials. The first dielectric layer 1011, second dielectric layer 1013, third dielectric layer 1017, and any additional optional dielectric layers can include Hafnium-Dioxide (HfO₂₎, Aluminum-Nitride (AlN), and/or any combination thereof. Further, each dielectric layer can include the same material or one or more dielectric layers can include different materials and/or combinations of materials. Back side metals can include Copper (Cu), Ruthenium (Ru), Co, and/or any combination thereof. Further, in some embodiments, the skilled artisan can appreciate that the multi-stack MIM capacitor structure 1001 can include one or more liners (not shown). Liners can include TaN or Ta or any combination thereof and each liner can include the same material or one or more liners can include different materials and/or combinations of materials.

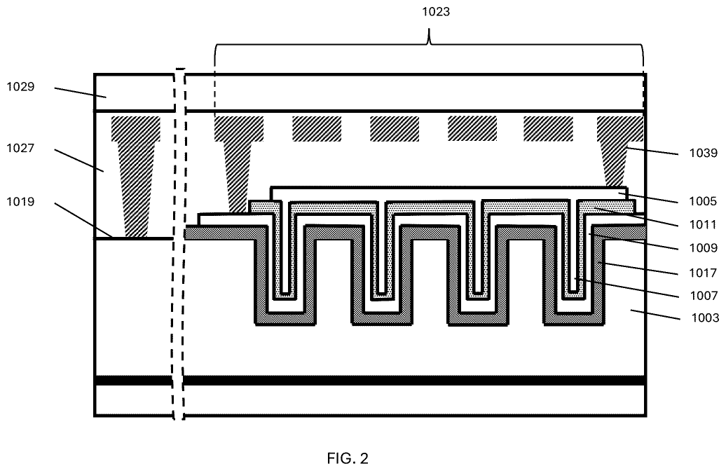

FIGS. 2-6 illustrate an exemplary technique for making a multi-stack metal-insulator-metal (MIM) capacitor 1001 for power integration. Referring to FIG. 2, a first side of the multi-stack MIM capacitor 1001 is formed on a front side 1019 of a substrate 1003 during manufacturing of a semiconductor structure. For example, a frontside plate 1005 and, optionally, a shared plate 1009 can be formed on the front side 1019 of the substrate 1003. Between the frontside plate 1005 and the shared plate 1009, a first dielectric layer 1011 can be formed. Between the shared plate 1009 and the substrate 1003, a third dielectric layer 1017 can be formed.

As shown in FIG. 2, the frontside plate 1005 can include fingers 1007 that extend downward (downward in reference to FIG. 2) into the substrate 1003. The fingers 1007 can extend perpendicularly (or substantially perpendicularly) from a plane of the frontside plate 1005. For example, the plane of the frontside plate 1005 can run parallel (or substantially parallel) to the front side 1019 of the substrate 1003 and the fingers 1007 can be perpendicular (or substantially perpendicular) to the plane of the frontside plate 1005 and the front side 1019 of the substrate 1003. That is, in some embodiments, a center axis of the fingers 1007 can be substantially perpendicular to the plane of the frontside plate 1005 and the front side 1019 of the substrate 1003. Further, in some embodiments, the sides of the fingers 1007 can be tapered, such as the fingers 1007 can have a greater width at one end than the other, though examples are not so limited. As used herein, the term “substantially” intends that the characteristic does not have to be absolute but sufficiently close enough so as to achieve the characteristic. For example, “substantially perpendicular” is not limited to absolute perpendicular and “substantially parallel” is not limited to absolute parallel. For instance, the fingers 1007 can be within .5°, 1°, 2°, 5°, etc. of absolutely perpendicular to the plane of the frontside plate 1005 and the front side 1019 of the substrate 1003. Further, the plane of the frontside plate 1005 can be within .5°, 1°, 2°, 5°, etc. of absolutely parallel to the front side 1019 of the substrate 1003.

The first dielectric layer 1011, formed on the frontside plate 1005 including the fingers 1007 of the frontside plate 1005, can follow a topography of the frontside plate 1005 and the fingers 1007 of the frontside plate 1005. The optional shared plate 1009 can further follow the topography of the first dielectric layer 1011. The third dielectric layer 1017 can follow the topography of the shared plate 1009. As such, the first dielectric layer 1011 and the optional shared plate 1009 and third dielectric layer 1017 can be formed to follow the topography of the frontside plate 1005 including the fingers 1007 of the frontside plate 1005. Further, additional shared plates and dielectric layers (not shown), formed to follow the topography of the frontside plate 1005 and the fingers 1007 can be contemplated.

A back-end-of-line (BEOL) wiring layer 1023 can be connected to the multi-stack MIM capacitor 1001. Vias 1039 can electrically connect metal lines of the BEOL wiring layer 1023 to the multi-stack MIM capacitor 1001 at plates (e.g., frontside plate 1005 and/or shared plates such as shared plate 1009 when the shared plate 1009 is located on the front side 1019 of the substrate 1003) of the multi-stack MIM capacitor 1001. The BEOL wiring layer 1023 can be connected to the multi-stack MIM capacitor 1001 at the front side 1019 of the substrate 1003. The first side of the multi-stack MIM capacitor 1001, the substrate 1003, and the BEOL wiring layer 1023 can then be bonded to a carrier wafer 1029. The BEOL wiring layer 1023 can be located between the multi-stack MIM capacitor 1001 and the carrier wafer 1029. A first interlayer dielectric (ILD) 1027 can fill the area between the first side of the multi-stack MIM capacitor 1001 and/or front side 1019 of the substrate 1003 and the carrier wafer 1029. As illustrated in FIG. 2, the carrier wafer 1029 can be located above (in reference to FIG. 2) the BEOL wiring layer 1023 and the first ILD 1027.

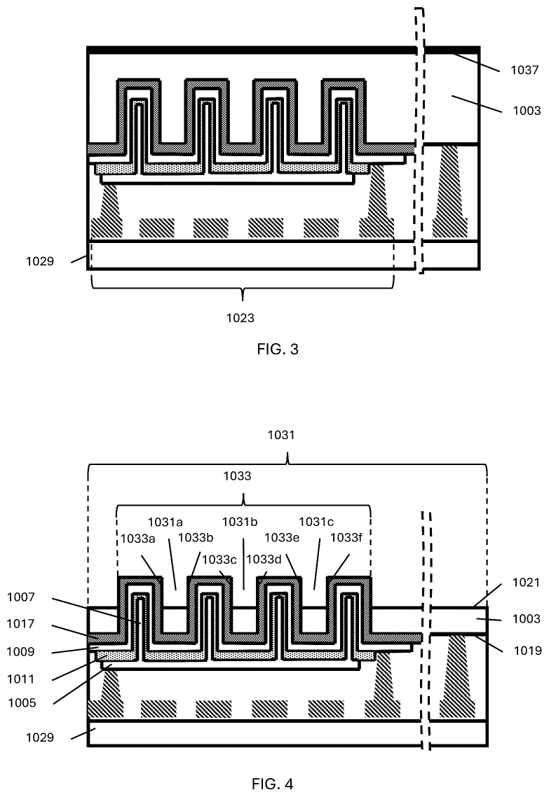

Referring now to FIG. 3, the semiconductor structure can be flipped so as the carrier wafer 1029, as illustrated in FIG. 3, is located below the BEOL wiring layer 1023. A portion of the substrate 1003 can be removed down to an etch stop layer 1037. The portion of the substrate 1003 can be removed by grinding the substrate 1003, planarizing the substrate 1003, etching the substrate 1003, or any other suitable and/or preferred method. Etching the substrate 1003 can include a wet etch, though examples are not so limited. Though flipping of the semiconductor structure is illustrated, other processes are contemplated and thus, the disclosure is not so limiting.

Continuing now with FIG. 4, the substrate 1003 can be recessed to a level where the dielectric layer in closest proximity to the substrate 1003 is exposed. For one non-limiting example, the substrate 1003 can be recessed to a level where the first dielectric layer 1011 is exposed. Further, for another non-limiting example, in an embodiment where the multi-stack MIM capacitor structure includes one shared plate and an additional dielectric layer, such as the third dielectric layer 1017 and the shared plate 1009 shown in FIG. 4, the substrate 1003 can be recessed to a level where the third dielectric layer 1017 is exposed. The substrate 1003 can be at least partially or fully recessed. In an embodiment where the substrate 1003 is at least partially recessed, the recessed substrate 1003 forms the back side 1021 of the substrate 1003, the back side 1021 of the substrate 1003 being opposite the front side 1019 of the substrate 1003. Recessing the substrate 1003 can form a trench 1031a or plurality of trenches 1031 (e.g., 1031a, 1031b, 1031c).

For example, FIG. 4 illustrates a multi-stack MIM capacitor structure including the shared plate 1009 and the third dielectric layer 1017. The third dielectric layer 1017 includes a plurality of side walls 1033 (e.g., side walls 1033a, 1033b, 1033c, 1033d, 1033e, 1033f). The substrate 1003 can be recessed to a level creating the trench 1031a or plurality of trenches 1031 between a first side wall 1033a and a second side wall 1033b of the plurality of side walls 1033 of the third dielectric layer 1017. The substrate 1003 can be recessed to a level where the fingers 1007 of the frontside plate 1005, the first dielectric layer 1011, the shared plate 1009, and the third dielectric layer 1017 extend from the front side 1019 of the substrate 1003 up through the back side 1021 of the substrate 1003.

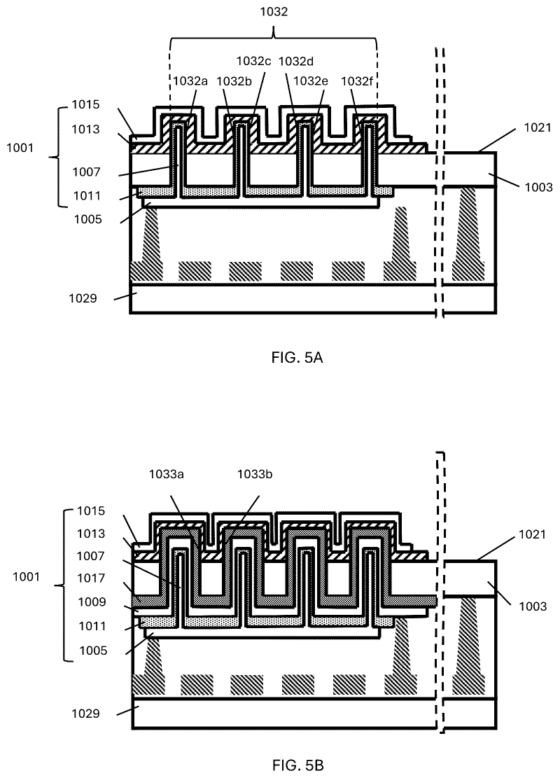

Turning now to FIG. 5A. In some embodiments, the dielectric layer of the multi-stack MIM capacitor 1001 in closest proximity to the substrate 1003 can be the first dielectric layer 1011. The first dielectric layer 1011 can include a plurality of side walls 1032 (e.g., side walls 1032a, 1032b, 1032c, 1032d, 1032e, 1032f). The substrate 1003 can be recessed to a level creating the trench 1031a or plurality of trenches 1031 (such as trenches 1031 shown in FIG. 4) between a first side wall 1032a and a second side wall 1032b of the plurality of side walls 1032 of the first dielectric layer 1011. The substrate 1003 can be recessed to a level where the fingers 1007 of the frontside plate 1005 and the first dielectric layer 1011 extend from the front side 1019 of the substrate 1003 up through the back side 1021 of the substrate 1003.

The substrate 1003 can be recessed to a thickness between 50 nm and 1 μm. In one or more embodiments, the substrate 1003 can be recessed to approximately 150 nm. Accordingly, the substrate 1003 can be recessed to a thickness that can be compatible with a backside power distribution network buried power rail (BSPDN BPR) scheme for power integration.

FIG. 5A further illustrates a second side of the multi-stack MIM capacitor 1001 formed on the back side 1021 of the substrate 1003. The second side of the multi-stack MIM capacitor 1001 includes a backside plate 1015 and a second dielectric layer 1013. The second dielectric layer 1013 can be formed between the back side 1021 of the substrate 1003 and the backside plate 1015. The backside plate 1015 and the second dielectric layer 1013 can be formed and/or developed utilizing a pattering and deposition process. For example, a conventional lithography, etching, and deposition known to one skilled in the art can be used. Both the second dielectric layer 1013 and the backside plate 1015 can conform to the topography of the fingers 1007 of the frontside plate 1005 and the first dielectric layer 1011. In some embodiments, the second dielectric layer 1013 and the backside plate 1015 can further conform to the topography of the back side 1021 of the substrate 1003 (e.g., in the example in which the substrate 1003 is at least partially recessed), though examples are not so limiting.

The second dielectric layer 1013 and the backside plate 1015 can be formed within the trench or plurality of trenches. The second dielectric layer 1013 and the backside plate 1015 can fill, or at least partially fill, the trench or plurality of trenches and can lie between the first side wall 1032a and the second side wall 1032b of the plurality of side walls 1032 of the first dielectric layer 1011.

Further, FIG. 5B illustrates a second side of the multi-stack MIM capacitor 1001 formed on the back side 1021 of the substrate 1003. In some embodiments, as illustrated in FIG. 5B, the backside plate 1015 and the second dielectric layer 1013 can be formed and/or developed, utilizing the pattering and deposition process, to conform to the topography of the fingers 1007 of the frontside plate 1005, the first dielectric layer 1011, and the optional shared plate 1009 and the third dielectric layer 1017. In some embodiments, the second dielectric layer 1013 and the backside plate 1015 can further conform to the topography of the back side 1021 of the substrate 1003 (e.g., in the example in which the substrate 1003 is at least partially recessed), though examples are not so limiting. The second dielectric layer 1013 and the backside plate 1015 can be formed within the trench or plurality of trenches. The second dielectric layer 1013 and the backside plate 1015 can fill, or at least partially fill, the trench or plurality of trenches and can lie between the first side wall 1033a and the second side wall 1033b of the plurality of side walls of the third dielectric layer 1017. Though one shared plate (shared plate 1009) and one additional dielectric layer (third dielectric layer 1017) are illustrated in FIG. 5B, examples are not so limited and additional shared plates and dielectric layers can be contemplated.

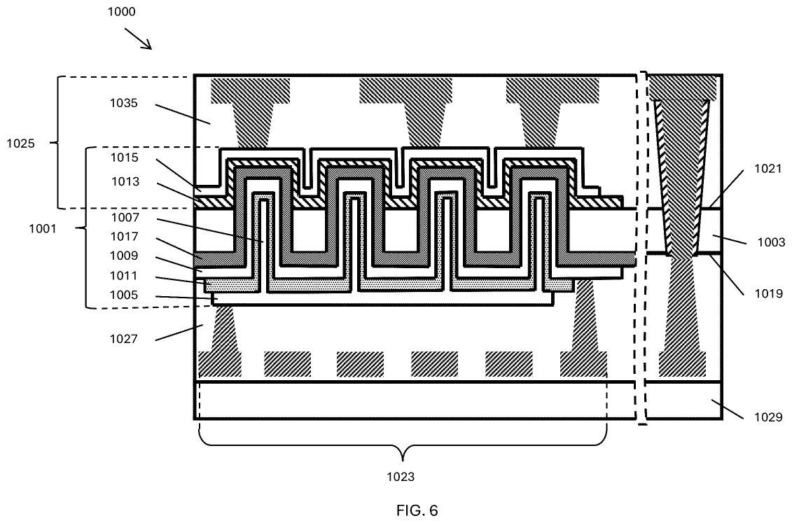

FIG. 6 illustrates the multi-stack MIM capacitor 1001 of a semiconductor structure 1000 formed on a substrate 1003, bonded to a carrier wafer 1029. The multi-stack MIM capacitor 1001 including a first side where the frontside plate 1005, including the fingers 1007, the first dielectric layer 1011, and the optional shared plate 1009 and third dielectric layer 1017 are formed on the front side 1019 of the substrate 1003 and a second side where the second dielectric layer 1013 and the backside plate 1015 are formed on the back side 1021 of the substrate 1003. The second dielectric layer 1013 and the backside plate 1015 are formed between side walls of a plurality of side walls (1033 as shown in FIGS. 4 and 5B, 1032 as shown in FIG. 5A) of the dielectric layer in closest proximity to the substrate 1003 (third dielectric layer 1017 as shown in FIGS. 4 and 5B, first dielectric layer 1011 as shown in FIG. 5A). The multi-stack MIM capacitor 1001 can be connected to a back-end-of-line (BEOL) wiring layer 1023 at the first side of the multi-stack MIM capacitor 1001. A second interlayer dielectric (ILD) 1035 can fill the back side 1021 of the substrate 1003 (i.e., at the second side of the multi-stack MIM capacitor 1001) and a first ILD 1027 can fill the front side of the substrate 1003 (i.e., at the first side of the multi-stack MIM capacitor 1001). The second dielectric layer 1013, the backside plate 1015, and the second ILD 1035 can be formed at a backside power distribution network (BSPDN) 1025 of the semiconductor structure 1000. In some non-limiting embodiments, vias can connect the BSPDN 1025 to the multi-stack MIM capacitor 1001 at plates (e.g., backside plate 1015) of the multi-stack MIM capacitor 1001, though examples herein are not so limited. Accordingly, in some embodiments, the BSPDN 1025 can be connected to the multi-stack MIM capacitor 1001 at the back side 1021 of the substrate 1003.

FIG. 7 illustrates an example of a transistor structure/region 7998 of a semiconductor structure. Note the carrier 1029, ILD 1027, gate contact 7041 and associated wiring (also referred to as via wiring), silicon fins 7045, gate cuts 7043, high-K metal gate (HKMG) 7999, back side gate contact 7039 with associated wiring (also referred to as backside via wiring), and second ILD 1035. Some embodiments can include the transistor structure co-integrated with a metal-insulator-metal (MIM) capacitor structure (MIM capacitor structure 1001 as shown in FIGS. 1 and 6). In some embodiments, the transistor structure can be a FinFET (fin Field-Effect Transistor) structure, though examples are not so limited. In some examples, the transistor structure can be a double or a multi-gate structure.

The transistor structure can be built on a substrate (e.g., same substrate as the MIM capacitor structure 1001 shown in FIGS. 1-6). FIG. 7 illustrates a transistor structure/region 7998 including HKMG 7999 and fins 7045. The fins 7045 can form channels of the transistor structure. One skilled in the art can appreciate that, in some embodiments the transistor structure can include several fins 7045 arranged side-by-side, associated with a single gate 7999, though examples are not so limited. Source and drain regions can be above and below the plane of the page.

A back-end-of-line (BEOL) wiring layer 1023 can be located on one side of the substrate and can include via wiring 7041 connecting the BEOL wiring layer 1023 to the gate 7999 of the transistor structure. In some embodiments, a first interlayer dielectric (ILD) 1027 can fill an area surrounding the BEOL wiring layer 1023 and the via wiring 7041. Further, a backside power delivery network (BSPDN) 1025 can be located on an opposite side of the substrate and can include a backside via wiring 7039 connecting the BSPDN 1025 to the gate 7999 of the transistor structure. In some embodiments, a second interlayer dielectric (ILD) 1035 can fill an area surrounding the BSPDN 1025 and the backside via wiring 7039. Further, the BEOL wiring layer 1023, the transistor structure/region 7998, and the BSPDN 1025 can be bonded to a carrier wafer 1029 (e.g., same carrier wafer 1029 as shown in FIGS. 2-6). In some embodiments, the BEOL wiring layer 1023 can be located between the transistor structure and the carrier wafer 1029.

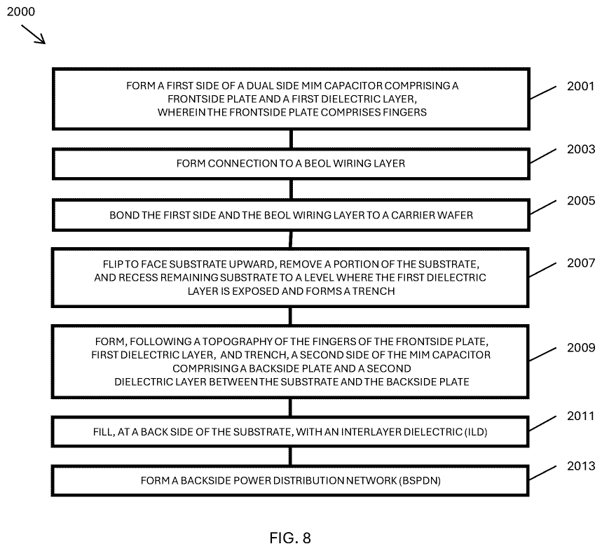

FIG. 8 illustrates an example of a method 2000 for making a dual side multi-stack metal-insulator-metal (MIM) capacitor for power integration. The method 2000 can be performed on a substrate/wafer during manufacturing of a semiconductor structure utilizing the dual side multi-stack MIM capacitor. The method 2000 can be performed on a whole substrate/wafer, prior to singulation of the substrate/wafer.

At 2001, the method 2000 includes forming a first side of the dual side multi-stack MIM capacitor on a first side of a substrate, the first side of the dual side multi-stack MIM capacitor including a frontside plate and a first dielectric layer between the frontside plate and the substrate. The frontside plate includes fingers extending into the substrate.

Optionally, the method 2000 can further include forming one or more shared plates and additional dielectric layers between the first dielectric layer and the substrate. For example, the method 2000 can include forming a first shared plate and a third dielectric layer where the first shared plate can be located between the first dielectric layer and the third dielectric layer and the third dielectric layer can be located between the shared plate and the substrate. In some embodiments, the method 2000 can further include forming multiple alternating shared plates and additional dielectric layers. For example, a second shared plate and a fourth dielectric layer can be formed in which the second shared plate can be located between the third dielectric layer and the fourth dielectric layer and the fourth dielectric layer can be located between the second shared plate and the substrate. Further, a third shared plate and a fifth dielectric layer can be formed in which the third shared plate can be located between the fourth dielectric layer and the fifth dielectric layer and the fifth dielectric layer can be located between the third shared plate and the substrate. Optionally, additional shared plates and dielectric layers are contemplated.

At 2003, the method 2000 includes forming connections to a back-end-of-line (BEOL) wiring layer. Metal lines of the BEOL wiring layer can be connected to the first side of the dual side multi-stack MIM capacitor. At 2005, the method 2000 includes bonding the first side of the dual side multi-stack MIM capacitor, the substrate, and the BEOL wiring layer to a carrier wafer.

At 2007, the method 2000 further includes flipping the substrate to face the substrate upward and removing a portion of the substrate. Removing of the portion of the substrate can include reducing a thickness of the substrate by grinding the substrate, planarizing the substrate, and/or etching the substrate. The substrate can be reduced down to an etch stop layer of the substrate. The method at 2007 further includes recessing a remaining substrate to a level where the first dielectric layer is exposed, the recession forming a trench and/or plurality of trenches. The trench and/or plurality of trenches can be formed between a plurality of side walls of the first dielectric layer (e.g., as illustrated in FIG. 5A, a trench can be formed between a first side wall 1032a and a second side wall 1032b). The remaining substrate can be at least partially recessed or can be fully recessed to form the trench and/or plurality of trenches. In some embodiments, the backside plate and the second dielectric layer can be formed after at least partially recessing or fully recessing the remaining substrate from the back side of the substrate. Further, recessing the remaining substrate to the level where the first dielectric layer is exposed can include recessing the substrate from a back side of the substrate and removal of the etch stop layer.

In some embodiments, the method includes recessing the remaining substrate to a thickness between 50 nm and 1 μm. In one or more embodiments, the substrate can be recessed to a thickness of 150 nm. Advantageously, the recessed substrate can include a thickness compatible with a backside power distribution network buried power rail (BSPDN BPR) scheme for power integration, though examples are not so limited.

At 2009, the method 2000 includes forming, by following a topography of the fingers of the frontside plate, the first dielectric layer, and the trench and/or plurality of trenches, a second side of the dual side multi-stack MIM capacitor on a back side of the substrate, the second side of the dual side multi-stack MIM capacitor including a backside plate and a second dielectric layer between the substrate and the backside plate. The second dielectric layer and the backside plate can be formed between the plurality of side walls of the first dielectric layer (i.e., between the first side wall and the second side wall). In embodiments that include at least one shared plate and additional dielectric layer, the second dielectric layer and the backside plate can further be formed, at least in part, between a plurality of side walls of the dielectric layer in closest proximity to the substrate.

At 2011, the method 2000 includes filling, at a back side of the substrate, with a second interlayer dielectric (ILD) and at 2013, the method 2000 includes forming a backside power distribution network (BSPDN) for power integration. The BSPDN can be connected to the second side of the dual side multi-stack MIM capacitor. The second ILD can fill an area around the second side of the multi-stack MIM capacitor, the BSPDN, and connections (e.g., vias). A first ILD can fill an area around the first side of the multi-stack MIM capacitor, the BEOL wiring layer, and connections (e.g., vias 1039 as illustrated in FIG. 2).

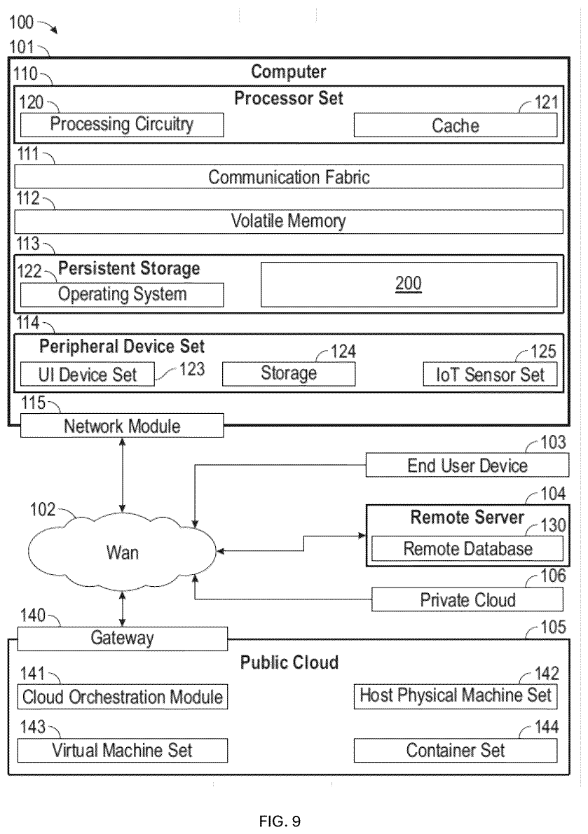

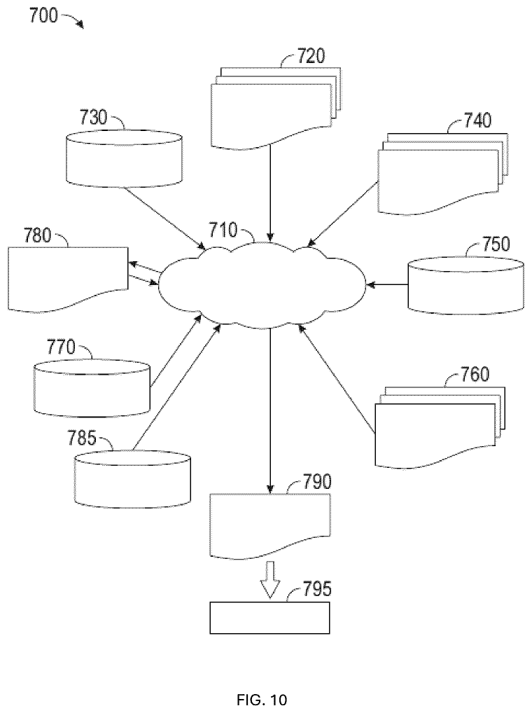

Reference should now be had to FIG. 9, which illustrates a computing environment according to an embodiment of the present invention (e.g., for implementing a design process such as that of FIG. 10).

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks can be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium can be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random-access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a system 200 for semiconductor design and/or control of semiconductor fabrication (see FIG. 9). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 can take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method can be distributed among multiple computers and/or between multiple locations. On the other hand, in this presentation of computing environment 100, detailed discussion is focused on a single computer, specifically computer 101, to keep the presentation as simple as possible. Computer 101 can be located in a cloud, even though it is not shown in a cloud in FIG. 9. On the other hand, computer 101 is not required to be in a cloud except to any extent as can be affirmatively indicated.

PROCESSOR SET 110 includes one, or more, computer processors of any type now known or to be developed in the future. Processing circuitry 120 can be distributed over multiple packages, for example, multiple, coordinated integrated circuit chips. Processing circuitry 120 can implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set can be located “off chip.” In some computing environments, processor set 110 can be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods can be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports, and the like. Other types of signal communication paths can be used, such as fiber optic communication paths and/or wireless communication paths.

VOLATILE MEMORY 112 is any type of volatile memory now known or to be developed in the future. Examples include dynamic type random-access memory (RAM) or static type RAM. Typically, volatile memory 112 is characterized by random-access, but this is not required unless affirmatively indicated. In computer 101, the volatile memory 112 is located in a single package and is internal to computer 101, but, alternatively or additionally, the volatile memory can be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 can be a read only memory (ROM), but typically at least a portion of the persistent storage allows writing of data, deletion of data, and re-writing of data. Some familiar forms of persistent storage include magnetic disks and solid state storage devices. Operating system 122 can take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 can be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 can include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 can be persistent and/or volatile. In some embodiments, storage 124 can take the form of a quantum computing storage device for storing data in the form of qubits. In embodiments where computer 101 is required to have a large amount of storage (for example, where computer 101 locally stores and manages a large database) then this storage can be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor can be a thermometer and another sensor can be a motion detector.

NETWORK MODULE 115 is the collection of computer software, hardware, and firmware that allows computer 101 to communicate with other computers through WAN 102. Network module 115 can include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 can be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and can take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 can be a client device, such as thin client, heavy client, mainframe computer, desktop computer, and so on.

REMOTE SERVER 104 is any computer system that serves at least some data and/or functionality to computer 101. Remote server 104 can be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data can be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs can be stored as images and can be transferred among and between the various physical machine hosts, either as images or after instantiation of the VCE. Cloud orchestration module 141 manages the transfer and storage of images, deploys new instantiations of VCEs, and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is illustrated as being in communication with WAN 102, in other embodiments a private cloud can be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

### Exemplary Design Process Used in Semiconductor Design, Manufacture, and/or Test

One or more embodiments make use of computer-aided semiconductor integrated circuit design simulation, test, layout, and/or manufacture. In this regard, FIG. 10 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 can be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines can include: lithography machines, machines and/or equipment for generating masks (e.g., e-beam writers), computers or equipment for simulating design structures, any apparatus used in the manufacturing or test process, or any machines for programming functionally equivalent representations of the design structures into any medium (e.g., a machine for programming a programmable gate array).

Design flow 700 can vary depending on the type of representation being designed. For example, a design flow 700 for building an application specific IC (ASIC) can differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 10 illustrates multiple such design structures including an input design structure 720 that is preferably processed by a design process 710. Design structure 720 can be a logical simulation design structure generated and processed by design process 710 to produce a logically equivalent functional representation of a hardware device. Design structure 720 can also or alternatively comprise data and/or program instructions that when processed by design process 710, generate a functional representation of the physical structure of a hardware device. Whether representing functional and/or structural design features, design structure 720 can be generated using electronic computer-aided design (ECAD) such as implemented by a core developer/designer. When encoded on a gate array or storage medium or the like, design structure 720 can be accessed and processed by one or more hardware and/or software modules within design process 710 to simulate or otherwise functionally represent an electronic component, circuit, electronic or logic module, apparatus, device, or system. As such, design structure 720 can comprise files or other data structures including human and/or machine-readable source code, compiled structures, and computer executable code structures that when processed by a design or simulation data processing system, functionally simulate or otherwise represent circuits or other levels of hardware logic design. Such data structures can include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which can contain design structures such as design structure 720. Netlist 780 can comprise, for example, compiled or otherwise processed data structures representing a list of wires, discrete components, logic gates, control circuits, I/O devices, models, etc. that describes the connections to other elements and circuits in an integrated circuit design. Netlist 780 can be synthesized using an iterative process in which netlist 780 is resynthesized one or more times depending on design specifications and parameters for the device. As with other design structure types described herein, netlist 780 can be recorded on a machine-readable data storage medium or programmed into a programmable gate array. The medium can be a nonvolatile storage medium such as a magnetic or optical disk drive, a programmable gate array, a compact flash, or other flash memory. Additionally, or in the alternative, the medium can be a system or cache memory, buffer space, or other suitable memory.

Design process 710 may include hardware and software modules for processing a variety of input data structure types including Netlist 780. Such data structure types can reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types can further include design specifications 740, characterization data 750, verification data 760, design rules 770, and test data files 785 which can include input test patterns, output test results, and other testing information. Design process 710 can further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 can also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the illustrated supporting data structures along with any additional mechanical design or data (if applicable), to generate a second design structure 790. Design structure 790 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 can comprise a compiled, executable HDL simulation model that functionally simulates the devices to be analyzed.

Design structure 790 can also employ a data format used for the exchange of layout data of integrated circuits and/or symbolic data format (e.g., information stored in a GDSII (GDS2), GL1, OASIS, map files, or any other suitable format for storing such design data structures). Design structure 790 can comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 can then proceed to a stage 795 where, for example, design structure 790: proceeds to tape-out, is released to manufacturing, is released to a mask house, is sent to another design house, is sent back to the customer, etc.

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching.” For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1 ) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method can utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense. Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom,” “top,” “above,” “over,” “under,” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a multi-stack metal-insulator-metal (MIM) capacitor structure comprising:
a substrate;
a frontside plate comprising fingers extending into the substrate;
a first dielectric layer located between the frontside plate and the substrate;
a backside plate; and
a second dielectric layer located between the backside plate and the substrate,
wherein the backside plate and the second dielectric layer conform to a topography of the fingers of the frontside plate and the first dielectric layer.

2. The semiconductor structure of claim 1, wherein the substrate is between 50 nm and 1 μm (150 nm) thick.

3. The semiconductor structure of claim 1, wherein the substrate comprises a front side and the frontside plate and the first dielectric layer are located at the front side of the substrate.

4. The semiconductor structure of claim 3, further comprising a back-end-of-line (BEOL) wiring layer, wherein the multi-stack MIM capacitor structure is connected to the BEOL wiring layer of the semiconductor structure at the front side of the substrate.

5. The semiconductor structure of claim 1, further comprising a transistor structure, wherein the MIM capacitor structure is co-integrated with the transistor structure.

6. The semiconductor structure of claim 3, wherein the substrate further comprises a back side and the second dielectric and the backside plate are located at the back side of the substrate.

7. The semiconductor structure of claim 6, wherein the fingers of the frontside plate and the first dielectric layer extend through the substrate from the front side of the substrate through the back side of the substrate.

8. The semiconductor structure of claim 6, further comprising a backside power distribution network (BSPDN) connected to the multi-stack MIM capacitor structure.

9. The semiconductor structure of claim 8, wherein the BSPDN is connected to the multi-stack MIM capacitor structure at the back side of the substrate.

10. The semiconductor structure of claim 1, wherein the frontside plate is of a first material and the backside plate is of a second material, different than the first material.

11. The semiconductor structure of claim 1, wherein the frontside plate is of a first thickness and the backside plate is of a second thickness, different than the first thickness.

12. The semiconductor structure of claim 1, wherein the first dielectric layer is of a first dielectric material and the second dielectric layer is of a second dielectric material, different than the first dielectric material.

13. The semiconductor structure of claim 1, wherein the first dielectric layer is of a first dielectric thickness and the second dielectric layer is of a second dielectric thickness.

14. The semiconductor structure of claim 1, further comprising:
a shared plate located at a front side of the substrate between the first dielectric layer and the substrate; and
a third dielectric layer located between the shared plate and the substrate,
wherein the shared plate and the third dielectric layer extend through the substrate from the front side of the substrate through a back side of the substrate.

15. The semiconductor structure of claim 14, wherein:
the frontside plate is of a first material, the backside plate is of a second material, and the shared plate is of a third material, different than the first material and the second material; and
the frontside plate is of a first thickness, the backside plate is of a second thickness, and the shared plate is of a third thickness, different than the first thickness and the second thickness.

16. The semiconductor structure of claim 14, wherein:
the first dielectric layer is of a first dielectric material, the second dielectric layer is of a second dielectric material, and the third dielectric layer is of a third dielectric material, different than the first dielectric material and the second dielectric material; and
the first dielectric layer is of a first dielectric thickness, the second dielectric layer is of a second dielectric thickness, and the third dielectric layer is of a third dielectric thickness, different than the first dielectric thickness and the second dielectric thickness.

17. A method for forming a semiconductor structure comprising:
forming a first side of a dual side multi-stack metal-insulator-metal (MIM) capacitor (1001), the first side comprising a frontside plate and a first dielectric layer located between the frontside plate and a front side of a substrate of the dual side multi-stack MIM capacitor, wherein the frontside plate comprises fingers extending into the substrate;
forming connections to a back-end-of-line (BEOL) wiring layer;
bonding the first side of the dual side multi-stack MIM capacitor and the BEOL wiring layer to a carrier wafer;
flipping the semiconductor structure to face a back side of the substrate upward, removing a portion of the substrate, and recessing a remaining substrate to a level where the first dielectric layer is exposed, the recession forming a trench;
forming, by following a topography of the fingers of the frontside plate, the first dielectric layer, and the trench, a second side of the dual side multi-stack MIM capacitor, the second side comprising a backside plate and a second dielectric layer between the back side of the substrate and the backside plate;
filling, at the back side of the substrate, with an interlayer dielectric (ILD); and
forming a backside power distribution network (BSPDN).

18. The method of claim 17, wherein:
the first dielectric layer includes a plurality of side walls;
the substrate is at least partially or fully recessed from the back side of the substrate forming the trench between a first side wall and a second side wall of the plurality of side walls; and
forming the second dielectric layer and the backside plate to follow the topography of the fingers of the frontside plate, the first dielectric layer, and the trench comprises forming the second dielectric layer and the backside plate between the first side wall and the second side wall of the plurality of side walls.

19. The method of claim 17, further comprising:
forming a first shared plate and a third dielectric layer on the first side of the dual side multi-stack MIM capacitor, wherein the first dielectric layer is located between the frontside plate and the first shared plate and the third dielectric layer is located between the first shared plate and the substrate of the dual side multi-stack MIM capacitor; and
forming the second dielectric layer and the backside plate further follows a topography of the first shared plate and the third dielectric layer and comprises forming the second dielectric layer and the backside plate, at least in part, between a first side wall and a second side wall of a plurality of side walls of the third dielectric layer.

20. The method of claim 19, further comprising:
forming a second shared plate and a fourth dielectric layer on the first side of the dual side multi-stack MIM capacitor, wherein the first dielectric layer is located between the frontside plate and the first shared plate, the third dielectric layer is located between the first shared plate and the second shared plate, and the fourth dielectric layer is located between the second shared plate and the substrate of the dual side multi-stack MIM capacitor; and
forming the second dielectric layer and the backside plate further follows a topography of the second shared plate and the fourth dielectric layer and comprises forming the second dielectric layer and the backside plate, at least in part, between a first side wall and a second side wall of a plurality of side walls of the fourth dielectric layer.

21. A hardware description language (HDL) design structure encoded on a machine-readable data storage medium, the HDL design structure comprising elements that when processed in a computer-aided design system generates a machine-executable representation of a semiconductor structure, wherein the HDL design structure comprises:
semiconductor structure comprising:
a multi-stack metal-insulator-metal (MIM) capacitor structure comprising:
a substrate;
a frontside plate comprising fingers extending into the substrate;
a first dielectric layer located between the frontside plate and the substrate;
a backside plate; and
a second dielectric layer located between the backside plate and the substrate,
wherein the backside plate and the second dielectric layer conform to a topography of the fingers of the frontside plate and the first dielectric layer.

22. The hardware description language (HDL) design structure of claim 21, wherein the substrate is between 50 nm and 1 μm thick.

23. The hardware description language (HDL) design structure of claim 21, wherein the substrate comprises a front side and the frontside plate and the first dielectric layer are located at the front side of the substrate.

24. The hardware description language (HDL) design structure of claim 23, wherein the HDL design structure further comprises a back-end-of-line (BEOL) wiring layer, wherein the multi-stack MIM capacitor structure is connected to the BEOL wiring layer of the semiconductor structure.

25. The hardware description language (HDL) design structure of claim 24, wherein the BEOL wiring layer is connected to the multi-stack MIM capacitor structure at the front side of the substrate.
